(19) United States
(12) Patent Application Publication
(10) Pub. No.: US 2025/0374641 A1
(43) Pub. Date: Dec. 4, 2025

(54) TRANSISTOR STRUCTURES AND METHODS FOR FORMING THE SAME

(71) Applicant: Taiwan Semiconductor Manufacturing Company Limited, Hsinchu (TW)

(72) Inventors: Ming-Yen CHUANG, Hsinchu City (TW); Hai-Ching CHEN, Hsinchu City (TW); Wu-Wei TSAI, Taoyuan City (TW)

(21) Appl. No.: 18/677,989

(22) Filed: May 30, 2024

(51) Int. Cl. H01L 29/45; H01L 21/443; H01L 29/66; H01L 29/786

(52) U.S. Cl. CPC H10D 64/62; H01L 21/443; H10D 30/6756; H10D 99/00

(57) ABSTRACT

Transistor structures and methods thereof include one or more carrier injection layers at the interfaces between a semiconductor channel and source and drain electrodes. The one or more carrier injection layers may be engineered to facilitate the injection of charge carriers across the interfaces between the channel and the source and drain electrodes. The one or more carrier injection layers may include a material having a work function that is between the work function of the channel material and the work function of the source and drain electrodes to compensate for the injection barrier effect and provide improved device performance. Multiple carrier injection layers having different compositions may be utilized to provide for improved carrier injection while minimizing interface defect states.

### BACKGROUND

The semiconductor industry has grown due to continuous improvements in integration density of various electronic components (e.g., transistors, diodes, resistors, inductors, capacitors, etc.). For the most part, these improvements in integration density have come from successive reductions in minimum feature size, which allow more components to be integrated into a given area. In this regard, individual transistors, interconnects, and related structures have become increasingly smaller and there is an ongoing need to develop new materials, processes, and designs of semiconductor devices and interconnects to allow further progress.

Transistors made of oxide semiconductors are an attractive option for back-end-of-line (BEOL) integration since such transistors may be processed at low temperatures and thus, may not damage previously fabricated devices. For example, the fabrication conditions and techniques may not damage previously fabricated front-end-of-line (FEOL) devices. Circuits based on oxide semiconductor-based transistor devices may further include other components that may be fabricated in a BEOL process, such as capacitors, inductors, resistors, and integrated passive devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first structure prior to formation of a transistor structure according to various embodiments of the present disclosure.

FIG. 2 is a vertical cross-sectional view of an intermediate structure illustrating a first dielectric material layer over a substrate according to various embodiments of the present disclosure.

FIG. 3 is a vertical cross-section view of an intermediate structure showing a bottom gate electrode layer formed over the first dielectric material layer according to various embodiments of the present disclosure.

FIG. 4 is a vertical cross-section view of an intermediate structure showing a gate insulator layer formed over the bottom gate electrode layer according to various embodiments of the present disclosure.

FIG. 5 is a vertical cross-section view of an intermediate structure showing an active layer formed over the gate insulator layer according to various embodiments of the present disclosure.

FIG. 6 is a vertical cross-section view of an intermediate structure showing a second dielectric material layer formed over the active layer according to various embodiments of the present disclosure.

FIG. 7 is a vertical cross-section view of an intermediate structure illustrating a patterned mask formed over the second dielectric material layer according to various embodiments of the present disclosure.

FIG. 8 is a vertical cross-section view of an intermediate structure illustrating a pair of openings formed through the second dielectric material layer and the active layer according to various embodiments of the present disclosure.

FIG. 9 is a vertical cross-section view of an intermediate structure showing a carrier injection layer formed over the upper surface of the second dielectric material layer and over the sidewalls and bottom surfaces of the openings according to various embodiments of the present disclosure.

FIG. 10 is a vertical cross-section view of an intermediate structure following a planarization process that removes portions of the carrier injection layer from the upper surface of the second dielectric material layer according to various embodiments of the present disclosure.

FIG. 11 is a vertical cross-section view of an intermediate structure showing a conductive material layer formed over the upper surface of the second dielectric material layer and over the carrier injection layers within the openings according to various embodiments of the present disclosure.

FIG. 12 is a vertical cross-section view of a first transistor structure according to an embodiment of the present disclosure.

FIG. 13 is a vertical cross-sectional view of an intermediate structure showing a first carrier injection layer formed over the upper surface of a second dielectric material layer and over the sidewalls and bottom surfaces of openings formed through the second dielectric material layer and an active layer, and a second carrier injection layer formed over the first carrier injection layer according to various embodiments of the present disclosure.

FIG. 14 is a vertical cross-section view of an intermediate structure following a planarization process that removes portions of the first carrier injection layer and the second carrier injection layer from over the upper surface of the second dielectric material layer according to various embodiments of the present disclosure.

FIG. 15 is a vertical cross-section view of an intermediate structure showing a conductive material layer formed over the upper surface of the second dielectric material layer and over the second carrier injection layers within the openings according to various embodiments of the present disclosure.

FIG. 16 is a vertical cross-section view of a second transistor structure according to an embodiment of the present disclosure.

FIG. 17 is a vertical cross-sectional view of an intermediate structure showing a first carrier injection layer formed over the upper surface of a second dielectric material layer and over the sidewalls and bottom surfaces of openings formed through the second dielectric material layer and an active layer, a second carrier injection layer formed over the first carrier injection layer, and a third carrier injection layer formed over the second carrier injection layer according to various embodiments of the present disclosure.

FIG. 18 is a vertical cross-section view of an intermediate structure following a planarization process that removes portions of the first carrier injection layer, the second carrier injection layer, and the third carrier injection layer from over the upper surface of the second dielectric material layer according to various embodiments of the present disclosure.

FIG. 19 is a vertical cross-section view of an intermediate structure showing a conductive material layer formed over the upper surface of the second dielectric material layer and over the third carrier injection layers within the openings according to various embodiments of the present disclosure.

FIG. 20 is a vertical cross-section view of a third transistor structure according to an embodiment of the present disclosure.

FIG. 21 is a vertical cross-section view of an intermediate structure illustrating a pair of openings formed through a second dielectric material layer and into an active layer according to various embodiments of the present disclosure.

FIG. 22 is a vertical cross-section view of an intermediate structure showing a carrier injection layer formed over the upper surface of the second dielectric material layer and over the sidewalls and bottom surfaces of the openings according to various embodiments of the present disclosure.

FIG. 23 is a vertical cross-section view of a fourth transistor structure according to an embodiment of the present disclosure.

FIG. 24 is a vertical cross-section view of a fifth transistor structure according to an embodiment of the present disclosure.

FIG. 25 is a vertical cross-section view of a sixth transistor structure according to an embodiment of the present disclosure.

FIG. 26 is a vertical cross-section view of a seventh transistor structure according to an embodiment of the present disclosure.

FIG. 27 is a vertical cross-section view of an eighth transistor structure according to an embodiment of the present disclosure.

FIG. 28 is a vertical cross-section view of a ninth transistor structure according to an embodiment of the present disclosure.

FIG. 29 is a vertical cross-section view of a tenth transistor structure according to an embodiment of the present disclosure.

FIG. 30 is a vertical cross-section view of an eleventh transistor structure according to an embodiment of the present disclosure.

FIG. 31 is a vertical cross-section view of a twelfth transistor structure according to an embodiment of the present disclosure.

FIG. 32 is a flow diagram illustrating a method for fabricating a transistor structure according to various embodiments of the present disclosure.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments of this disclosure provide semiconductor device structures and methods that may be advantageous in terms of manufacturing flexibility, improved integration density, and increased computing power of semiconductor integrated circuit (IC) dies. In this regard, embodiment transistor structures are disclosed that may be formed in a BEOL process and may be incorporated with other BEOL circuit components such as capacitors, inductors, resistors, and integrated passive devices. As such, the transistor structures may include materials that may be processed at low temperatures and thus, may not damage previously fabricated devices (e.g., FEOL devices).

Related transistor structures are often plagued by poor device performance and reliability issues due to process damage occurring during the fabrication process, particularly at the contact regions between the semiconductor channel and the source and drain electrodes. This may lead to poor contact between the semiconductor channel and the source and drain electrodes which may result in low “on” current for the transistor structure and degraded performance.

In order to improve the performance and reliability of transistor structures, various embodiments disclosed herein include transistor structures and methods of forming thereof that include one or more carrier injection layers at the interfaces between the semiconductor channel and the source and drain electrodes. The one or more carrier injection layers may be engineered to facilitate the injection of charge carriers (i.e., electrons and/or holes) across the interfaces between the semiconductor channel and the respective source and drain electrodes.

In various embodiments, one or more carrier injection layers may include a material having a work function that is between the work function of the channel material and the work function of the source and drain electrodes. A large mismatch in work function between the channel and the source and drain electrodes may result in a relatively high barrier to the injection of charge carriers across the interfaces between the channel and the source and drain electrodes. This high injection barrier may contribute to low “on” current and poor performance of the transistor structure. In various embodiments, utilizing carrier injection layers having work function that is between the work functions of the channel and the electrodes may at least partially compensate for this barrier effect and provide improved device performance.

In some embodiments, multiple carrier injection layers may be provided at the interfaces between the semiconductor channel and the source and drain electrodes. The multiple carrier injection layers may have different compositions that may be engineered to promote carrier injection across the channel/electrode interface. In some embodiments, a first carrier injection layer contacting the semiconductor channel may have an amorphous structure while a second carrier injection layer may have a crystalline structure. This may provide for improved carrier injection while minimizing interface defect states.

Transistor structures according to various embodiments may include both bottom gate and top gate configurations and may be compatible with both BEOL and FEOL fabrication processes.

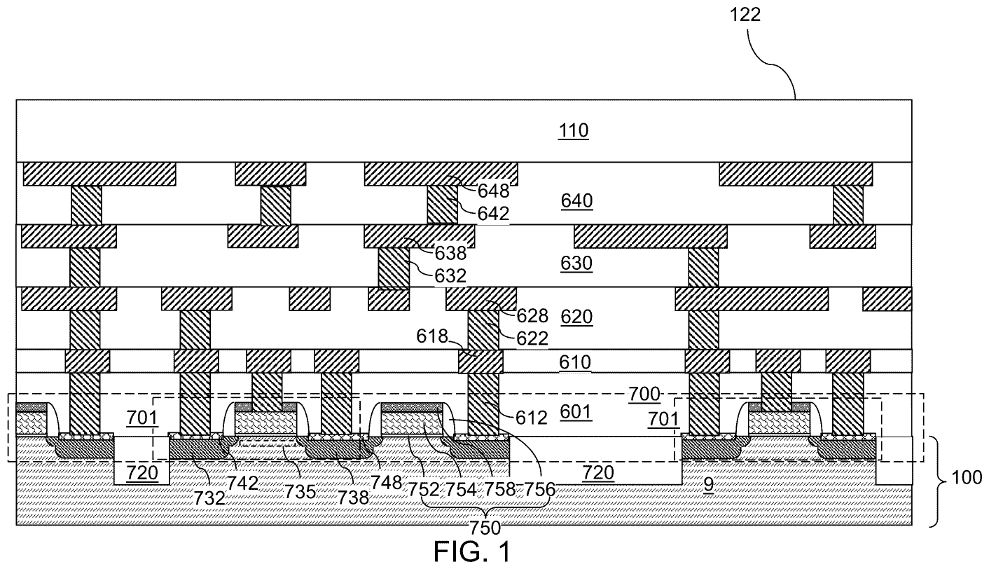

FIG. 1 is a vertical cross-sectional view of a first structure prior to formation of a transistor structure according to various embodiments of the present disclosure. The first structure includes a substrate 100, which may be a semiconductor substrate such as a commercially available silicon substrate. The substrate 100 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 100 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source electrode 732, a drain electrode 738, a semiconductor channel 735 that includes a surface portion of the substrate 100 extending between the source electrode 732 and the drain electrode 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source electrode 732, and a drain-side metal-semiconductor alloy region 748 may be formed on each drain electrode 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as CMOS circuitry 700.

One or more of the field effect transistors 701 in the CMOS circuitry 700 may include a semiconductor channel 735 that contains a portion of the semiconductor material layer 9 in the substrate 100. If the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a subset of the field effect transistors 701 in the CMOS circuitry 700 may include a respective node that is subsequently electrically connected to a node of a BEOL transistor structure to be subsequently formed.

In one embodiment, the substrate 100 may include a single crystalline silicon substrate, and the field effect transistors 701 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

The semiconductor devices 701 may be formed over the top surface of the semiconductor material layer 9 of the substrate 100 using front-end-of-line (FEOL) fabrication processes. Various metal interconnect structures formed within dielectric material layers may be subsequently formed over the substrate 100 and the semiconductor devices 701 thereupon (such as field effect transistors). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the CMOS circuitry 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, third metal line structures 638 formed in an upper portion of the third interconnect-level dielectric material layer 630, third metal via structures 642 formed in a lower portion of the fourth interconnect-level dielectric material layer 640, and fourth metal line structures 648 formed in an upper portion of the fourth interconnect-level dielectric material layer 640. While the present disclosure is described using an embodiment in which four levels metal line structures are formed in dielectric material layers, embodiments are expressly contemplated herein in which a lesser or greater number of levels of metal line structures are formed in dielectric material layers.

Each of the dielectric material layers (601, 610, 620, 630, 640) may include a dielectric material such as undoped silicate glass, a doped silicate glass, organosilicate glass, amorphous fluorinated carbon, porous variants thereof, or combinations thereof. In some embodiments, the dielectric material may include one or more of SiO₂, SiN, SiCN, SiON, or a suitable dielectric material having a dielectric constant, k, that is lower than 7. Each of the metal interconnect structures (612, 618, 622, 628, 631, 638, 642, 648) may include at least one conductive material, which may be a combination of a metallic liner (such as a metallic nitride or a metallic carbide) and a metallic fill material. Each metallic liner may include TIN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638, 648) and at least one underlying metal via structure (622, 632, 642) may be formed as an integrated line and via structure.

Generally, semiconductor devices 701 may be formed on a substrate 100, and metal interconnect structures (612, 618, 622, 628, 632, 638, 642, 648) and dielectric material layers (601, 610, 620, 630, 640) over the semiconductor devices 701. The metal interconnect structures (612, 618, 622, 628, 632, 638, 642, 648) may be formed in the dielectric material layers (601, 610, 620, 630, 640), and may be electrically connected to the semiconductor devices.

Referring again to FIG. 1, a first dielectric material layer 110 may be formed over the metal interconnect structures (612, 618, 622, 628, 632, 638, 642, 648) and dielectric material layers (601, 610, 620, 630, 640). The first dielectric material layer 110 may include a suitable dielectric material, such as silicon oxide, undoped silicate glass, a doped silicate glass, organosilicate glass, amorphous fluorinated carbon, porous variants thereof, or combinations thereof. In some embodiments, the dielectric material may include one or more of SiO₂, SIN, SiCN, SiON, or a suitable dielectric material having a dielectric constant, k, that is lower than 7. Other suitable dielectric materials are within the contemplated scope of disclosure. The first dielectric material layer 110 may be deposited using any suitable deposition process, such a chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like. In some embodiments, one or more above-described metal interconnect structures, such as integrated line and via structures, may be formed within the first dielectric material layer 110 and may be coupled to metal interconnect structures (612, 618, 622, 628, 632, 638, 642, 648) located within the underlying dielectric material layers (601, 610, 620, 630, 640). The first dielectric material layer 110 may include a planar upper surface 122.

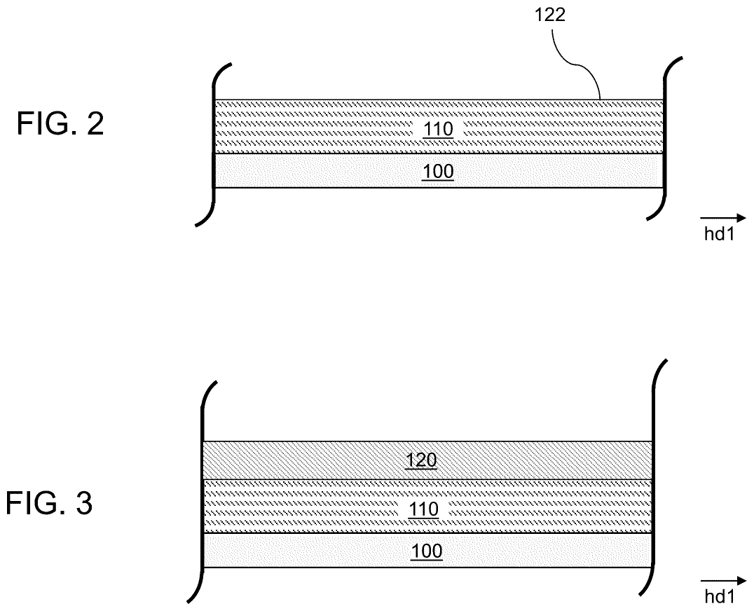

FIGS. 2-12 are sequential vertical cross-sectional views illustrating a process of forming a transistor structure according to various embodiments of the present disclosure. FIG. 2 is a vertical cross-sectional view of an intermediate structure illustrating a first dielectric material layer 110 over a substrate 100. The substrate 100 and the first dielectric material layer 110 may be similar to the substrate 100 and first dielectric material layer 110 described above with reference to FIG. 1. Thus, repeated discussion of like components is omitted for clarity. For clarity, FIG. 2 illustrates the first dielectric material layer 110 located directly over the substrate 100. However, it will be understood that the exemplary intermediate structure may additionally include semiconductor devices 701, metal interconnect structures (612, 618, 622, 628, 632, 638, 642, 648) and/or additional dielectric material layers (601, 610, 620, 630, 640) as described above located between the substrate 100 and the first dielectric material layer 110.

FIG. 3 is a vertical cross-section view of an intermediate structure showing a bottom gate electrode layer 120 formed over the first dielectric material layer 110 according to various embodiments of the present disclosure. Referring to FIG. 3, a bottom gate electrode layer 120 may be deposited on the first dielectric material layer 110. The bottom gate electrode layer 120 may include any suitable electrically conductive material, such as copper (Cu), aluminum (Al), zirconium (Zr), titanium (Ti), titanium nitride (TiN), tungsten (W), tantalum (Ta), tantalum nitride (TaN), molybdenum (Mo), ruthenium (Ru), palladium (Pd), platinum (Pt), cobalt (Co), nickel (Ni), iridium (Ir), iron (Fe), beryllium (Be), chromium (Cr), antimony (Sb), osmium (Os), thorium (Th), vanadium (V), alloys thereof, and combinations of the same. Other suitable electrically conductive materials for the bottom gate electrode layer 120 are within the contemplated scope of disclosure.

The bottom gate electrode layer 120 may be deposited using any suitable deposition process. For example, suitable deposition processes may include physical vapor deposition (PVD), sputtering, chemical vapor deposition (CVD), atomic layer deposition (ALD), plasma-enhanced chemical vapor deposition (PECVD), electrochemical deposition, or combinations thereof.

Although the bottom gate electrode layer 120 is shown as a continuous layer in FIG. 3, it will be understood that the bottom gate electrode 120 may be a discrete layer that may be laterally surrounded by a dielectric material. In some embodiments, the bottom gate electrode layer 120 may be patterned by removing select portions of the bottom gate electrode layer 120 (e.g., by etching portions of the bottom gate electrode layer through a patterned mask formed using photolithographic processes) to form one or more discrete patterned electrode layers 120 on the first dielectric layer 110. Then, additional dielectric material may be formed over the exposed surfaces of the first dielectric layer 110, the side surfaces of the patterned electrode layer, and optionally over the upper surface of the bottom gate electrode layer(s) 120 to embed the bottom gate electrode layer(s) 120 within the dielectric material.

Alternatively, the bottom gate electrode layer 120 may be formed within the first dielectric material layer 110. For example, a photoresist layer (not shown) may be deposited over the first dielectric material layer 110 and patterned using photolithographic techniques. The pattern of the photoresist layer may be transferred to the first dielectric layer 110 and thus, the portions of the first dielectric material layer 110 exposed through the photoresist layer may be etched to form one or more trenches. An electrically conductive material may be deposited in the one or more trenches, and a planarization process may be performed to planarize upper surfaces of the bottom gate electrode layer 120 and the first dielectric material layer 110 to provide one or more discrete bottom gate electrode layers 120 formed within the first dielectric material layer 110. Although FIG. 3 illustrates a single bottom gate electrode layer 120 over the first dielectric material layer 110, it will be understood that a plurality of bottom gate electrode layers 120 may be formed over the first dielectric material layer 110. Each bottom gate electrode layer 120 may serve as a gate electrode of a transistor structure as described further below.

In other embodiments, the bottom gate electrode layer 120 may be formed within a semiconductor material layer, such as semiconductor material layer 9 shown in FIG. 1.

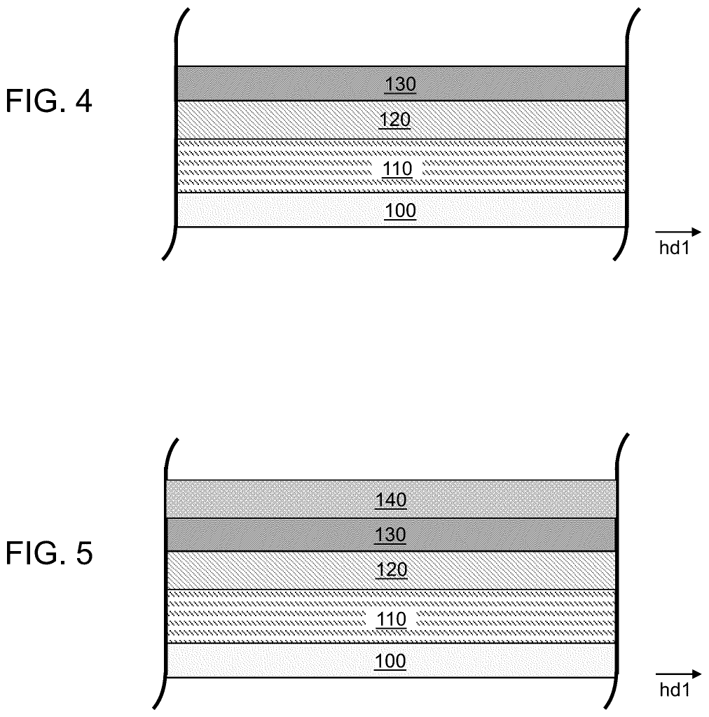

FIG. 4 is a vertical cross-section view of an intermediate structure showing a gate insulator layer 130 formed over the bottom gate electrode layer 120 according to various embodiments of the present disclosure. Referring to FIG. 4, the gate insulator layer 130 may include a suitable dielectric material, such as silicon oxide (SiOₓ), aluminum oxide (AlOₓ), hafnium oxide (HfOₓ), zirconium oxide (ZrOₓ), lanthanum oxide (LaOₓ), strontium oxide (SrOₓ), cerium oxide (CeOₓ) doped with hafnium zirconium oxide (HZO), and the like, including various combinations thereof (e.g., HfOx: ZrOx, HfOx: A1Ox; HfOx: LaOx,, HfOx: SiOx, HfOx: SrO, etc.). Other suitable dielectric materials are within the contemplated scope of disclosure. The gate insulator layer 130 may be a single layer or may include a multilayer structure, where the different layers may be composed of the same or different dielectric materials. The gate insulator layer 130 may be deposited using any suitable deposition process, such a chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like.

FIG. 5 is a vertical cross-section view of an intermediate structure showing an active layer 140 formed over the gate insulator layer 130 according to various embodiments of the present disclosure. Referring to FIG. 5, the active layer 140 may include a suitable semiconductor material, such as amorphous silicon, polycrystalline silicon, a metal oxide semiconductor material (e.g., indium zinc oxide (IZO), indium gallium oxide (IGO), indium gallium zinc oxide (IGZO), indium tungsten oxide (IWO), indium tungsten zinc oxide (IWZO), indium gallium zinc tin oxide (IGZTO), etc.), including various combinations thereof. Other suitable semiconductor materials for the active layer 140 are within the contemplated scope of disclosure. The active layer 140 may be deposited over the upper surface of the gate insulator layer 130 via a suitable deposition process, such as ALD, CVD, PECVD, PVD, etc. The active layer 140 may provide a channel region for one or more transistor structures as described further below.

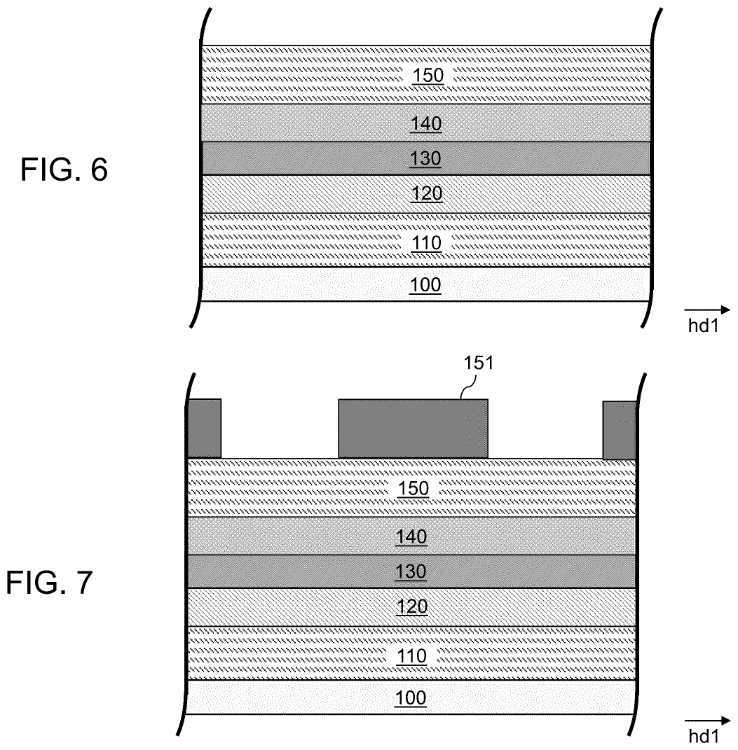

FIG. 6 is a vertical cross-section view of an intermediate structure showing a second dielectric material layer 150 formed over the active layer 140 according to various embodiments of the present disclosure. Referring to FIG. 6, the second dielectric material layer 150 may include a suitable dielectric material, such as silicon oxide, undoped silicate glass, a doped silicate glass, organosilicate glass, amorphous fluorinated carbon, porous variants thereof, or combinations thereof. In some embodiments, the dielectric material may include one or more of SiO₂, SiN, SiCN, SiON, or a suitable dielectric material having a dielectric constant, k, that is lower than 7. Other suitable dielectric materials are within the contemplated scope of disclosure. In some embodiments, the second dielectric material layer 150 may have the same composition as the first dielectric material layer 110. Alternatively, the second dielectric material layer 150 and the first dielectric material layer 110 may have different compositions. The second dielectric material layer 150 may be deposited using any suitable deposition process, such as CVD, PVD, ALD, HDPCVD, MOCVD, PECVD, sputtering, laser ablation, or the like.

FIG. 7 is a vertical cross-section view of an intermediate structure illustrating a patterned mask 151 formed over the second dielectric material layer 150 according to various embodiments of the present disclosure. The patterned mask 151 may be formed by depositing a layer of a photoresist material over the upper surface of the second dielectric material layer 150 and patterning the photoresist material using lithographic techniques to form a patterned photoresist mask 151 as shown in FIG. 7. Portions of the second dielectric material layer 150 may be exposed through openings in the patterned mask 151 as shown in FIG. 7.

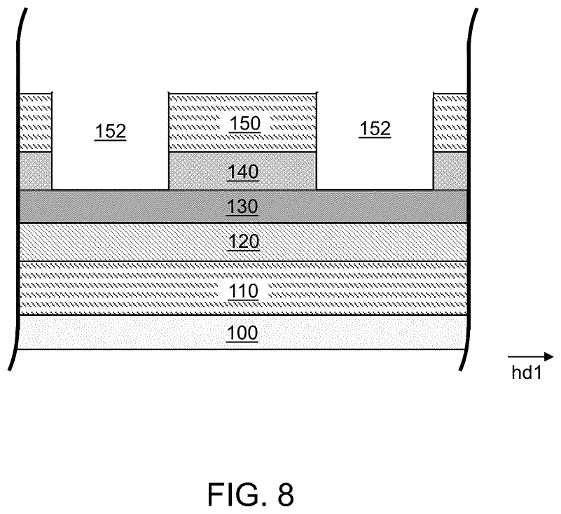

FIG. 8 is a vertical cross-section view of an intermediate structure illustrating a pair of openings 152 formed through the second dielectric material layer 150 and the active layer 140 according to various embodiments of the present disclosure. Referring to FIG. 8, an etching process, such as an anisotropic etching process, may be performed to remove portions of the second dielectric material layer 150 and the active layer 140 that are exposed through the patterned mask 151 to form the openings 152. The etching process may be stopped at the gate insulator layer 130. The second dielectric material layer 150 and the active layer 140 may be exposed along the sidewalls of the openings 152 and the gate insulator layer 130 may be exposed along the bottom surfaces of the openings 152. In some embodiments, the openings 152 through the second dielectric material layer 150 and the active layer 140 may be formed using a single etching step. Alternatively, multiple etching steps including different etch chemistries and/or other process conditions may be used to form the openings 152. For example, a first etching chemistry may be used to etch through portions of the second dielectric material layer 150 to the active layer 140, and a different second etching chemistry may be used to etch through portions of the active layer 140 to reach the gate insulator layer 130. Following the etching process, the patterned mask 151 may be removed by ashing or by dissolution with a solvent.

Referring again to FIG. 8, the openings 152 may be used to form source and drain electrodes electrically contacting the active layer 140 in the finished transistor structure. However, the above-described etching process and other processing steps used to form the source and drain electrodes may result in process damage occurring at the contact regions between the active layer 140 and the source and drain electrodes. This process damage may lead to poor contact between the active layer 140 and the source and drain electrodes which may result in low “on” current for the transistor structure and degraded performance.

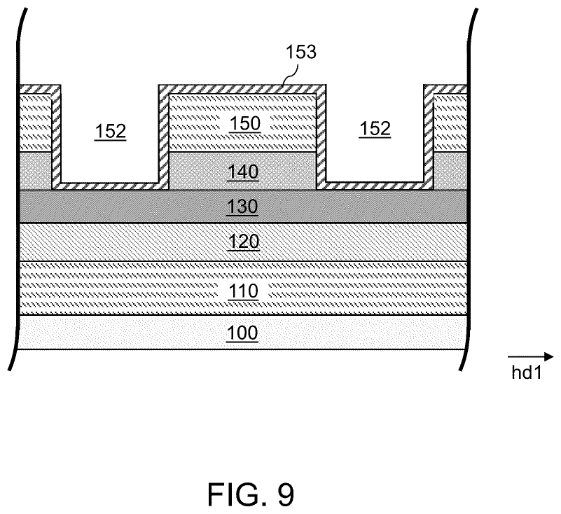

FIG. 9 is a vertical cross-section view of an intermediate structure showing a carrier injection layer 153 formed over the upper surface of the second dielectric material layer 150 and over the sidewalls and bottom surfaces of the openings 152 according to various embodiments of the present disclosure. Referring to FIG. 9, the carrier injection layer 153 may be deposited over the upper surface of the second dielectric material layer 150, over side surfaces of the second dielectric material layer 150 and the active layer 140 along the sidewalls of the openings 152 and over upper surfaces of the gate insulator layer 130 along the bottom surfaces of the openings 152. The carrier injection layer 153 may be deposited using a suitable deposition process as described above. In some embodiments, the carrier injection layer 153 may be deposited via atomic layer deposition (ALD) or physical vapor deposition (PVD), although it will be understood that other deposition methods may also be utilized.

In various embodiments, the carrier injection layer 153 may include a metal, a metal oxide and/or a metal nitride material, such as, for example, zinc oxide (ZnO). gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru). Other suitable materials for the carrier injection layer 153 are within the contemplated scope of disclosure. In various embodiments, a thickness of the carrier injection layer 153 may be 5 nm or less, such as 3 nm or less, including 1 nm or less. Such a thickness of the carrier injection layer 153 may provide sufficient area for the metal material(s) of the source electrode and drain electrode while maintaining suitable resistivity.

In various embodiments, a large mismatch in work function between the material of the active layer 140 and the material of the source electrode and the drain electrode may result in a relatively high barrier to the injection of charge carriers (i.e., electrons and/or holes) across the interfaces between the active layer 140 and the respective source electrode and drain electrode. This high injection barrier may contribute to low “on” current and poor performance of the transistor structure. In various embodiments, the carrier injection layer 153 may at least partially compensate for the high injection barrier by utilizing a material that has a work function that is between the work function of the material of the active layer 140 and the work function of the material of the source and drain electrodes. Accordingly, the effect of the large mismatch in work function between the active layer 140 and the source and drain electrodes may be reduced by utilizing a carrier injection layer 153 having a work function that is between the work functions of the active layer 140 and the source and drain electrodes.

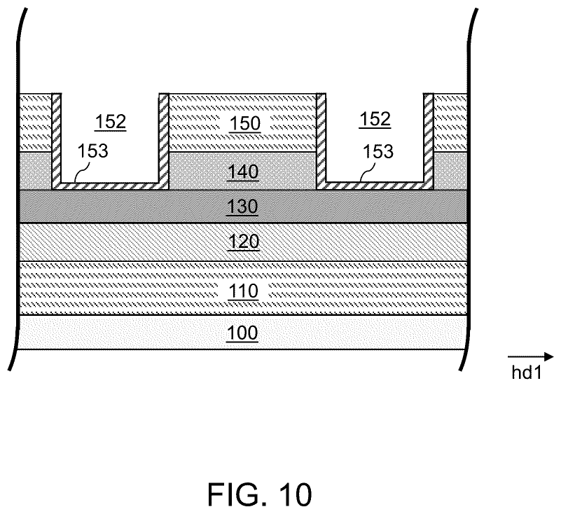

FIG. 10 is a vertical cross-section view of an intermediate structure following a planarization process that removes portions of the carrier injection layer 153 from the upper surface of the second dielectric material layer 150 according to various embodiments of the present disclosure. Referring to FIG. 10, a planarization process, such as a chemical-mechanical planarization (CMP) process, may be used to remove portions of the carrier injection layer 153 from over the upper surface of the second dielectric material layer 150. Following the planarization process, discrete carrier injection layers 153 may be located over side surfaces of the second dielectric material layer 150 and the active layer 140 along the sidewalls of the openings 152 and over upper surfaces of the gate insulator layer 130 along the bottom surfaces of the openings 152.

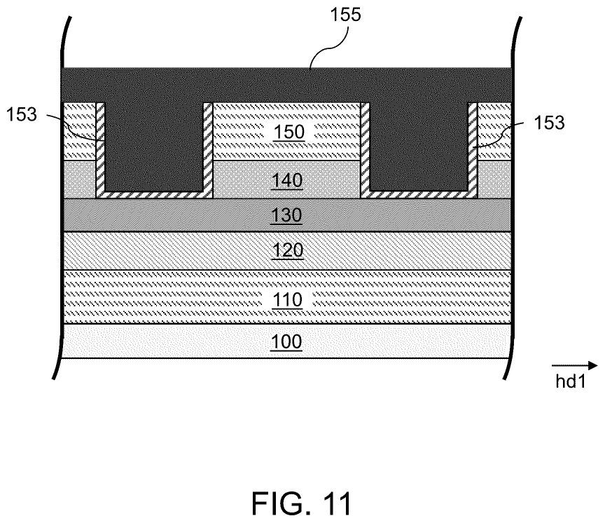

FIG. 11 is a vertical cross-section view of an intermediate structure showing a conductive material layer 155 formed over the upper surface of the second dielectric material layer 150 and over the carrier injection layers 153 within the openings 152 according to various embodiments of the present disclosure. Referring to FIG. 11, the conductive material layer 155 may be deposited over the upper surface of the second dielectric material layer 150 and over the carrier injection layers 153 within each of the openings 152. The conductive material layer 155 may fill the remaining volume of each of the openings 152. The conductive material layer 155 may include any suitable electrically conductive material, such as copper (Cu), aluminum (Al), zirconium (Zr), titanium (Ti), titanium nitride (TiN), tungsten (W), tantalum (Ta), tantalum nitride (TaN), molybdenum (Mo), ruthenium (Ru), palladium (Pd), platinum (Pt), cobalt (Co), nickel (Ni), iridium (Ir), iron (Fe), beryllium (Be), chromium (Cr), antimony (Sb), osmium (Os), thorium (Th), vanadium (V), alloys thereof, and combinations of the same. Other suitable electrically conductive materials for conductive material layer 155 are within the contemplated scope of disclosure. In some embodiments, the conductive material layer 155 may be composed of the same material(s) as the bottom gate electrode layer 120. Alternatively, the conductive material layer 155 and the bottom gate electrode layer 120 may have different compositions. The conductive material layer 155 may be deposited using a suitable deposition process, such as via physical vapor deposition (PVD), sputtering, chemical vapor deposition (CVD), atomic layer deposition (ALD), plasma-enhanced chemical vapor deposition (PECVD), electrochemical deposition, or combinations thereof.

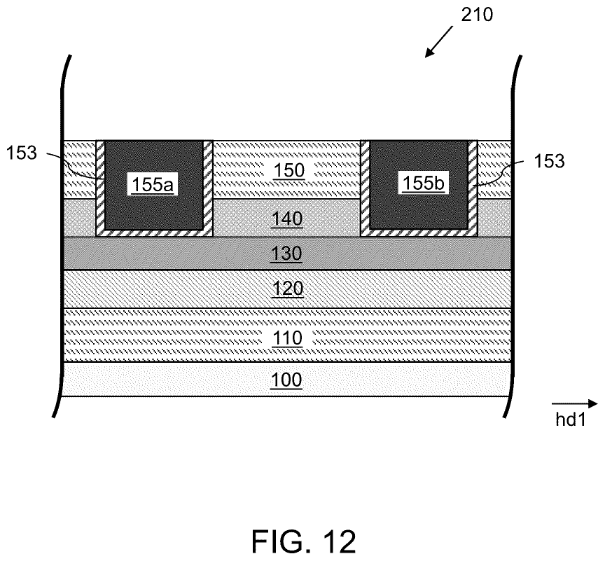

FIG. 12 is a vertical cross-section view of a first transistor structure 210 according to an embodiment of the present disclosure. Referring to FIG. 12, a planarization process, such as a CMP process, may be performed to remove portions of the conductive material layer 155 from over the upper surface of the second dielectric material layer 150 to provide discrete first electrode and second electrode (155a and 155b). The first transistor structure 210 may include a bottom gate electrode layer 120 that is separated from the active layer 140 by a gate insulator layer 130. The first electrode 155a and second electrode 155b may function as a source electrode and a drain electrode of the first transistor structure 210. It will be understood that the first electrode 155a and the second electrode 155b may refer to a source electrode or a drain electrode, individually or collectively, dependent upon the context. The active layer 140 may provide a channel region between the source electrode and drain electrodes (155a and 155b). A carrier injection layer 153 laterally surrounds each of the source electrode and drain electrodes (155a and 155b) and is located between each of the source electrode and drain electrodes (155a and 155b) and the active layer 140. Bottom surfaces of the carrier injection layers 153 contact the gate insulator layer 130. The carrier injection layers 153 each include a material having a work function that is between the work function of the source electrode and drain electrodes (155a and 155b) and the work function of the active layer 140. In some embodiments, the carrier injection layers 153 may include one or more of zinc oxide (ZnO). gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru).

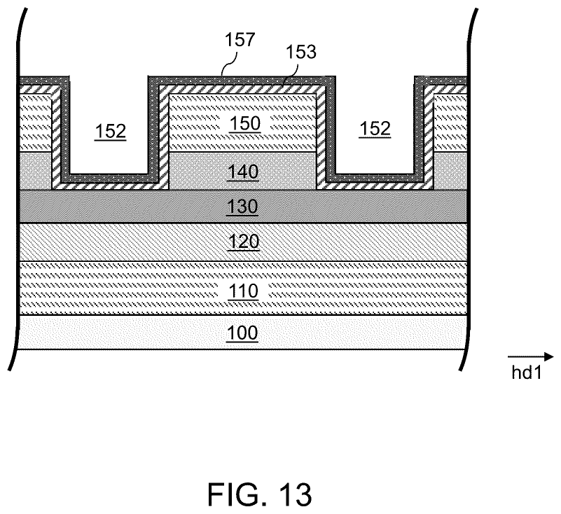

FIGS. 13-16 are sequential vertical cross-sectional views illustrating a process of forming a transistor structure according to another embodiment of the present disclosure. FIG. 13 is a vertical cross-sectional view of an intermediate structure that may be derived from the intermediate structure shown in FIG. 9. Thus, repeated discussion of like elements is omitted for brevity. The intermediate structure of FIG. 13 may differ from the intermediate structure of FIG. 9 in that the carrier injection layer 153 may be a first carrier injection layer 153, and a second carrier injection layer 157 may be formed over the first carrier injection layer 153. Referring to FIG. 13, the first carrier injection layer 153 may be deposited over the upper surface of the second dielectric material layer 150, over side surfaces of the second dielectric material layer 150 and the active layer 140 along the sidewalls of the openings 152 and over upper surfaces of the gate insulator layer 130 along the bottom surfaces of the openings 152, and the second carrier injection layer 157 may be deposited over the first carrier injection layer 153. The first carrier injection layer 153 and the second carrier injection layer 157 may each be deposited using a suitable deposition method as described above, such as via ALD or PVD.

In various embodiments, the first carrier injection layer 153 and the second carrier injection layer 157 may be composed of different materials. Suitable materials for the first carrier injection layer 153 may include, without limitation, indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO). In some embodiments, the first carrier injection layer 153 may have an amorphous structure. An amorphous first carrier injection layer 153 may be more suitable for contacting the side surfaces of the active layer 140 due to lower interface defect states. This may further facilitate injection of charge carriers between the active layer 140 and the source/drain electrodes in the transistor structure. In some embodiments, the first carrier injection layer 153 may be a metal oxide material including indium and at least one other metal element. In some embodiments, the first carrier injection layer 153 may have a different composition than the active layer 140. Alternatively, the first carrier injection layer 153 and the active layer 140 may be composed of the same materials.

Suitable materials for the second carrier injection layer 157 may include, without limitation, zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti). The second carrier injection layer 157 may have a crystalline or an amorphous structure. In some embodiments, the work function of the second carrier injection layer 157 may be between the work function of the active layer 140 and the work function of the source and drain electrodes. In some embodiments, the work functions of both the first carrier injection layer 153 and the second carrier injection layer 157 may be between the work function of the active layer 140 and the work function of the source and drain electrodes.

In various embodiments, a thickness of the first carrier injection layer 153 may be less than 5 nm, such as 2 nm or less, including 1 nm or less. A thickness of the second carrier injection layer 157 may be less than 5 nm, such as 2 nm or less, including 1 nm or less. A total thickness of the first carrier injection layer 153 and the second carrier injection layer 157 may be 5 nm or less, such as 3 nm or less, including 1 nm or less. Such a thickness of the carrier injection layer 153 may provide sufficient area for the metal material(s) of the source electrode and drain electrode while maintaining suitable resistivity.

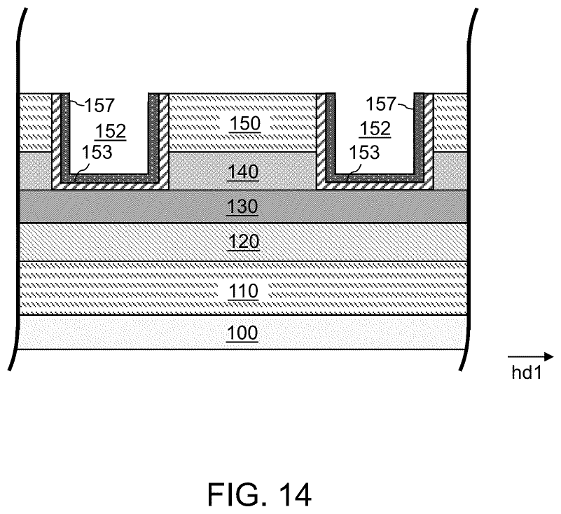

FIG. 14 is a vertical cross-section view of an intermediate structure following a planarization process that removes portions of the first carrier injection layer 153 and the second carrier injection layer 157 from over the upper surface of the second dielectric material layer 150 according to various embodiments of the present disclosure. Following the planarization process, discrete first carrier injection layers 153 and second carrier injection layers 157 may be located over side surfaces of the second dielectric material layer 150 and the active layer 140 along the sidewalls of the openings 152 and over upper surfaces of the gate insulator layer 130 along the bottom surfaces of the openings 152. The first carrier injection layers 153 may contact side surfaces of the active layer 140 and the upper surface of the gate insulator layer 130. The second carrier injection layers 157 may be located over the first carrier injection layers 153.

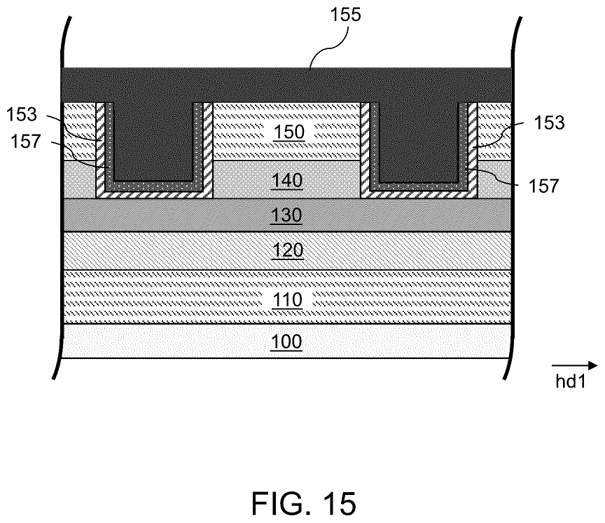

FIG. 15 is a vertical cross-section view of an intermediate structure showing a conductive material layer 155 formed over the upper surface of the second dielectric material layer 150 and over the second carrier injection layers 157 within the openings 152 according to various embodiments of the present disclosure. Referring to FIG. 15, the conductive material layer 155 may be deposited over the upper surface of the second dielectric material layer 150 and over the second carrier injection layers 157 within each of the openings 152. The conductive material layer 155 may fill the remaining volume of each of the openings 152. The conductive material layer 155 may include any suitable electrically conductive material as described above with reference to FIG. 12. The conductive material layer 155 may be deposited using a suitable deposition process as described above.

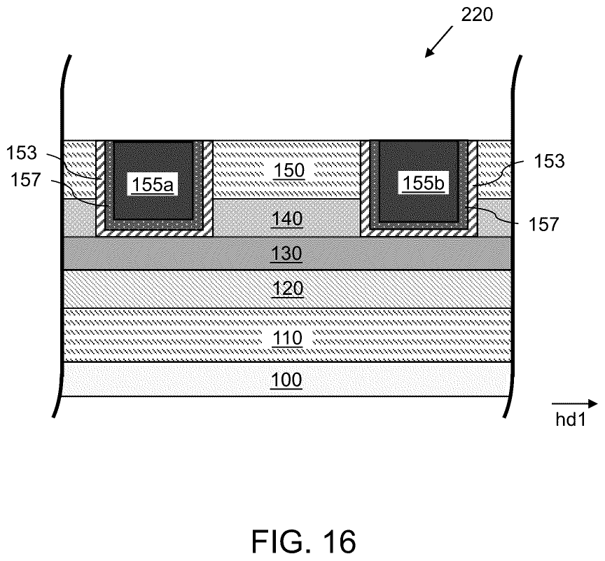

FIG. 16 is a vertical cross-section view of a second transistor structure 220 according to an embodiment of the present disclosure. Referring to FIG. 16, a planarization process, such as a CMP process, may be performed to remove portions of the conductive material layer 155 from over the upper surface of the second dielectric material layer 150 to provide discrete first electrode 155a and second electrode 155b. The second transistor structure 220 may include a bottom gate electrode layer 120 that is separated from the active layer 140 by a gate insulator layer 130. The first electrode 155a and second electrode 155b may function as source and drain electrodes of the second transistor structure 220. The active layer 140 may provide a channel region between the source electrode and drain electrode (155a and 155b). A first carrier injection layer 153 and a second carrier injection layer 157 laterally surround each of the source electrode and drain electrode (155a and 155b). Each first carrier injection layer 153 contacts side surfaces of the second dielectric material layer 150 and the active layer 140 and the upper surface of the gate insulator layer 130. Each second carrier injection layer 157 is located between, and contacts, both a first carrier injection layer 153 and either a first electrode 155a or a second electrode 155b. In some embodiments, the first carrier injection layers 153 may have an amorphous structure. In some embodiments, the first carrier injection layers 153 may be composed of a metal oxide material including indium and at least one additional metal (e.g., IZO, IGO, IGZO, IWO, IWZO, IGZTO, etc.). In some embodiments, the first carrier injection layers 153 and the active layer 140 may have an amorphous structure. In some embodiments, both the second carrier injection layers 157 and the first and second electrodes 155a and 155b may have a crystalline structure. In some embodiments, the work function of the second carrier injection layers 157 may be between the work functions of the active layer 140 and the first electrode 155a and second electrode 155b. In some embodiments, the work functions of both the first carrier injection layers 153 and the second carrier injection layers 157 may be between the work functions of the active layer 140 and the first electrode 155a and second electrode 155b.

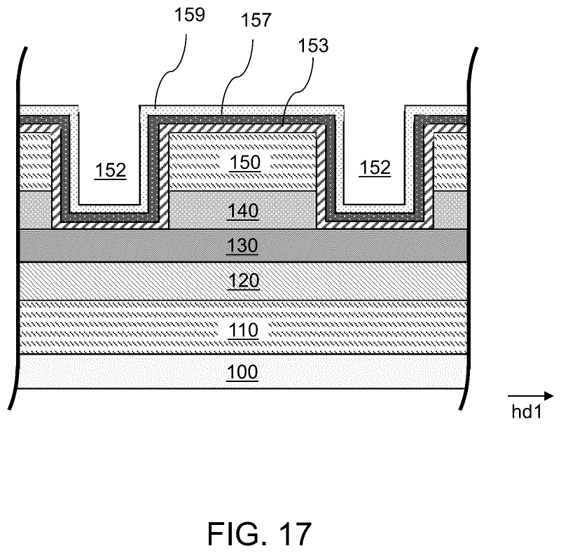

FIGS. 17-20 are sequential vertical cross-sectional views illustrating a process of forming a transistor structure according to another embodiment of the present disclosure. FIG. 17 is a vertical cross-sectional view of an intermediate structure that may be derived from the intermediate structure shown in FIG. 13. Thus, repeated discussion of like elements is omitted for brevity. The intermediate structure of FIG. 17 may differ from the intermediate structure of FIG. 13 in that a third carrier injection layer 159 may be formed over the second carrier injection layer 157. Referring to FIG. 17, the first carrier injection layer 153 may be deposited over the upper surface of the second dielectric material layer 150, over side surfaces of the second dielectric material layer 150 and the active layer 140 along the sidewalls of the openings 152 and over upper surfaces of the gate insulator layer 130 along the bottom surfaces of the openings 152. The second carrier injection layer 157 may be deposited over the first carrier injection layer 153. The third carrier injection layer 159 may be deposited over the second carrier injection layer 157. The first carrier injection layer 153, the second carrier injection layer 157, and the third carrier injection layer 159 may each be deposited using a suitable deposition method as described above, such as via ALD or PVD.

Suitable materials for the first carrier injection layer 153 may include, without limitation, indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO). In some embodiments, the first carrier injection layer 153 may have an amorphous structure. As discussed above, an amorphous first carrier injection layer 153 may be more suitable for contacting the side surfaces of the active layer 140 due to lower interface defect states. In some embodiments, the first carrier injection layer 153 may be a metal oxide material including indium and at least one other metal element. In some embodiments, the first carrier injection layer 153 may have a different composition than the active layer 140. Alternatively, the first carrier injection layer 153 and the active layer 140 may be composed of the same materials.

Suitable materials for the second carrier injection layer 157 may include, without limitation, zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti). The second carrier injection layer 157 may have a crystalline or an amorphous structure. In some embodiments, the work function of the second carrier injection layer 157 may be between the work function of the active layer 140 and the work function of the source and drain electrodes.

Suitable materials for the third carrier injection layer 159 may include, without limitation, indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO). In some embodiments, the third carrier injection layer 159 may have an amorphous structure. In some embodiments, the third carrier injection layer 159 may be a metal oxide material including indium and at least one other metal element.

In some embodiments, the second carrier injection layer 157 may have a different composition than both the first carrier injection layer 153 and the third carrier injection layer 159. In some embodiments, the third carrier injection layer 159 may have a different composition than the first carrier injection layer 153. Alternatively, the third carrier injection layer 159 and the first carrier injection layer 153 may be composed of the same materials. In some embodiments, the second carrier injection layer 157 may include a crystalline material that may be sandwiched between (i.e., disposed between) an amorphous first carrier injection layer 153 and an amorphous third carrier injection layer 159.

In some embodiments, the work functions of the first carrier injection layer 153, the second carrier injection layer 157, and the third carrier injection layer 159 may be between the work function of the active layer 140 and the work function of the source and drain electrodes.

In various embodiments, a thickness of the first carrier injection layer 153 may be less than 5 nm, such as 2 nm or less, including 1 nm or less. A thickness of the second carrier injection layer 157 may be less than 5 nm, such as 2 nm or less, including 1 nm or less. A thickness of the third carrier injection layer 159 may be less than 5 nm, such as 2 nm or less, including 1 nm or less. In some embodiments, a total thickness of the first carrier injection layer 153, the second carrier injection layer 157, and the third carrier injection layer 159 may be 5 nm or less. Such a thickness of the carrier injection layer 153 may provide sufficient area for the metal material(s) of the source electrode and drain electrode while maintaining suitable resistivity.

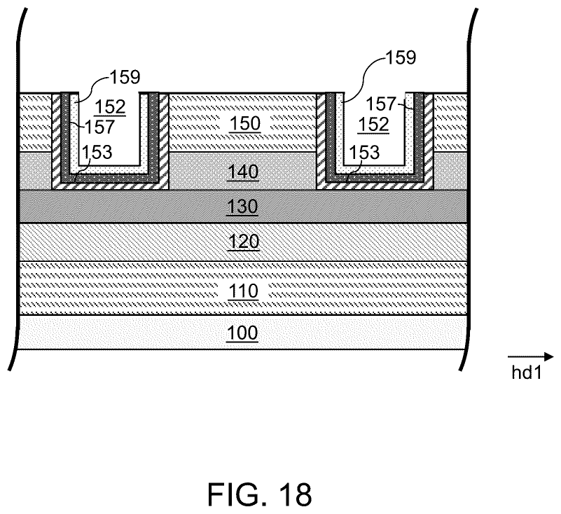

FIG. 18 is a vertical cross-section view of an intermediate structure following a planarization process that removes portions of the first carrier injection layer 153, the second carrier injection layer 157, and the third carrier injection layer 159 from over the upper surface of the second dielectric material layer 150 according to various embodiments of the present disclosure. Following the planarization process, discrete first carrier injection layers 153, second carrier injection layers 157, and third carrier injection layers 159 may be located over side surfaces of the second dielectric material layer 150 and the active layer 140 along the sidewalls of the openings 152 and over upper surfaces of the gate insulator layer 130 along the bottom surfaces of the openings 152. The first carrier injection layers 153 may contact side surfaces of the active layer 140 and the upper surface of the gate insulator layer 130. The second carrier injection layers 157 may be located over the first carrier injection layers 153, and the third carrier injection layers 159 may be located over the second carrier injection layers 157.

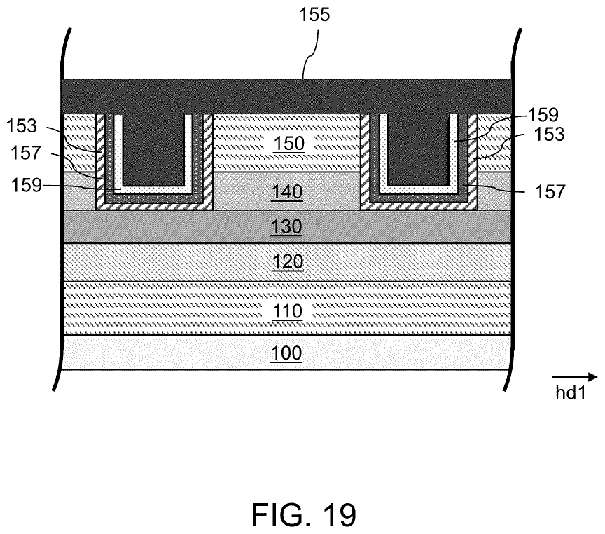

FIG. 19 is a vertical cross-section view of an intermediate structure showing a conductive material layer 155 formed over the upper surface of the second dielectric material layer 150 and over the third carrier injection layers 159 within the openings 152 according to various embodiments of the present disclosure. Referring to FIG. 19, the conductive material layer 155 may be deposited over the upper surface of the second dielectric material layer 150 and over the third carrier injection layers 159 within each of the openings 152. The conductive material layer 155 may fill the remaining volume of each of the openings 152. The conductive material layer 155 may include any suitable electrically conductive material as described above with reference to FIG. 12. The conductive material layer 155 may be deposited using a suitable deposition process as described above.

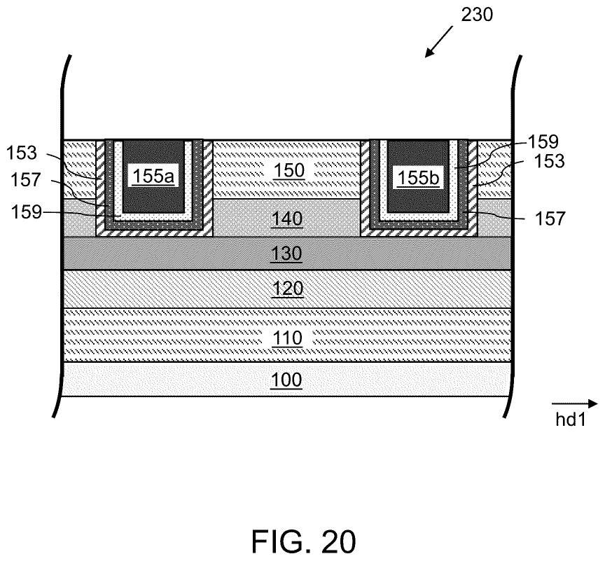

FIG. 20 is a vertical cross-section view of a third transistor structure 230 according to an embodiment of the present disclosure. Referring to FIG. 20, a planarization process, such as a CMP process, may be performed to remove portions of the conductive material layer 155 from over the upper surface of the second dielectric material layer 150 to provide discrete first electrode 155a and second electrode 155b. The third transistor structure 230 may include a bottom gate electrode layer 120 that is separated from the active layer 140 by a gate insulator layer 130. The first electrode 155a and second electrode 155b may function as source electrode and drain electrode of the third transistor structure 220. The active layer 140 may provide a channel region between the source electrode and drain electrode (155a and 155b). A first carrier injection layer 153, a second carrier injection layer 157, and a third carrier injection layer 159 laterally surround each of the source electrode and drain electrode (155a and 155b). Each first carrier injection layer 153 contacts side surfaces of the second dielectric material layer 150 and the active layer 140 and the upper surface of the gate insulator layer 130. Each third carrier injection layer 159 contacts either a first electrode 155a or a second electrode 155b. Each second carrier injection layer 157 is located between a first carrier injection layer 153 and a third carrier injection layer 159. In some embodiments, the first carrier injection layers 153 and the third carrier injection layers 159 may have an amorphous structure. In some embodiments, the first carrier injection layers 153 and the third carrier injection layers 159 may be composed of a metal oxide material including indium and at least one additional metal (e.g., IZO, IGO, IGZO, IWO, IWZO, IGZTO, etc.). In some embodiments, the first carrier injection layers 153, the third carrier injection layers 159 and the active layer 140 may have an amorphous structure. In some embodiments, both the second carrier injection layers 157 and the first electrode 155a and second electrode 155b may have a crystalline structure. In some embodiments, the work function of the second carrier injection layers 157 may be between the work functions of the active layer 140 and the first electrode 155a and second electrode 155b. In some embodiments, the work functions of the first carrier injection layers 153, the second carrier injection layers 157, and the third carrier injection layers 159 may be between the work functions of the active layer 140 and the first electrode 155a and second electrode 155b.

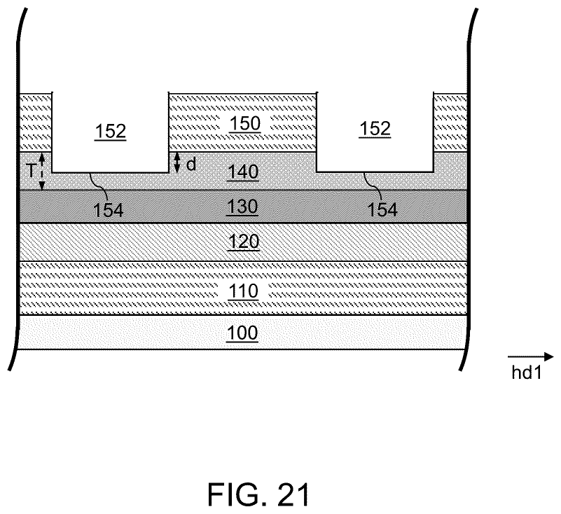

FIGS. 21-23 are sequential vertical cross-sectional views illustrating a process of forming a transistor structure according to another embodiment of the present disclosure. FIG. 21 is a vertical cross-section view of an intermediate structure illustrating a pair of openings 152 formed through the second dielectric material layer 150 and into the active layer 140 according to various embodiments of the present disclosure. The intermediate structure shown in FIG. 21 is similar to the intermediate structure shown in FIG. 8. Thus, repeated discussion of like elements is omitted for brevity. The intermediate structure of FIG. 21 differs from the intermediate structure of FIG. 8 in that the openings 152 do not extend through the entire thickness of the active layer 140 to expose the upper surface of the gate insulator layer 130 at the bottom of the openings 152.

The intermediate structure shown in FIG. 21 may be formed by performing an etching process as described above with reference to FIG. 8. However, the etching process may be stopped prior to reaching the gate insulator layer 130, leaving a portion of the active layer 140 remaining between the bottom of each opening 152 and the upper surface of the gate insulator layer 130. The active layer 140 may thus include recessed surfaces 154 that may form the bottom surfaces of each of the openings 152. The recessed surfaces 154 may be vertically recessed relative to the upper surface of the active layer 140 by a recess distance, d. In some embodiments, the recess distance, d, may be at least about 30%, including about 30-70%, of the total thickness, T, of the active layer 140 between the upper surface and the lower surface of the active layer 140. In some embodiments, the recess distance, d, may be a function of the etching process used to recess the surface of the active layer 140.

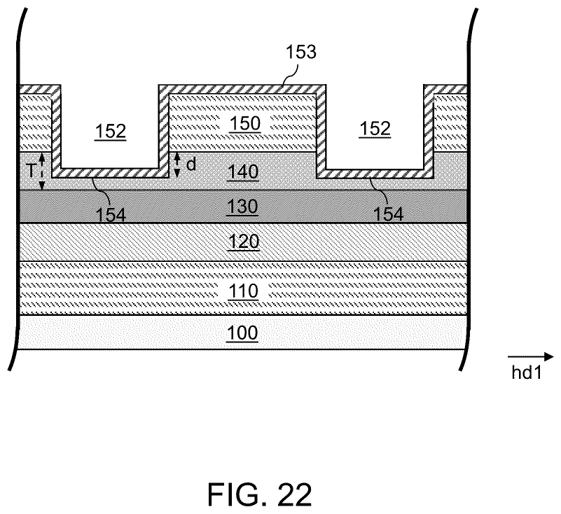

FIG. 22 is a vertical cross-section view of an intermediate structure showing a carrier injection layer 153 formed over the upper surface of the second dielectric material layer 150 and over the sidewalls and bottom surfaces of the openings 152 according to various embodiments of the present disclosure. Referring to FIG. 21, the carrier injection layer 153 may be deposited over the upper surface of the second dielectric material layer 150, over side surfaces of the second dielectric material layer 150 and the active layer 140 along the sidewalls of the openings 152 and over the recessed surfaces 154 of the active layer 140 on the bottom of the openings 152. The carrier injection layer 153 may be equivalent to the carrier injection layer 153 described above with respect to FIG. 9. Thus, repeated discussion of the details of the carrier injection layer 153 is omitted for brevity. The intermediate structure shown in FIG. 22 may be different from the intermediate structure of FIG. 9 in that the carrier injection layer 153 may not contact the gate insulator layer 130. In various embodiments, a bottom surface of the carrier injection layer 153 may be recessed relative to the upper surface of the active layer 140 by a recess distance, d, that is at least about 30%, including about 30-70%, of the total thickness, T, of the active layer 140.

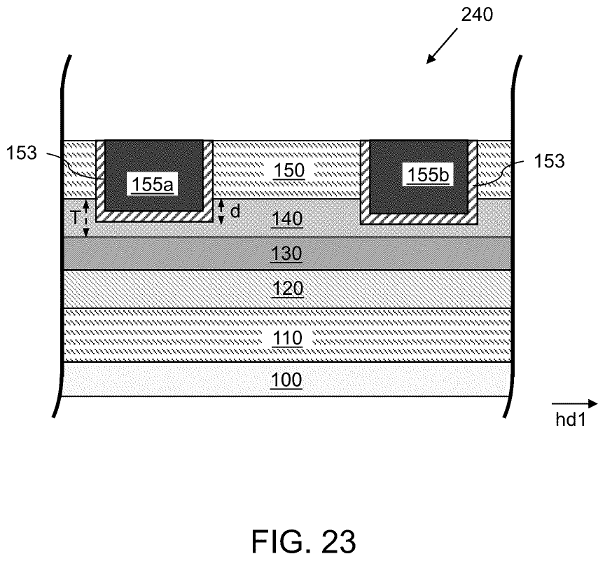

FIG. 23 is a vertical cross-section view of a fourth transistor structure 240 according to an embodiment of the present disclosure. Referring to FIG. 23, a planarization process may be performed to remove portions of the carrier injection layer 153 from over the upper surface of the second dielectric material layer 150 to provide discrete carrier injection layers 153 within the openings 152, as described above with reference to FIG. 10, and a conductive material layer may be deposited over the upper surface of the second dielectric material layer 150 and over the carrier injection layers 153 within the openings 152, as described above with reference to FIG. 11. Then, a planarization process as described above with reference to FIG. 12 may be performed to remove excess portions of the conductive material layer 155 to provide discrete first electrode 155a and second electrode 155b contacting the carrier injection layers 153.

The fourth transistor structure 240 may include a bottom gate electrode layer 120 that is separated from the active layer 140 by a gate insulator layer 130. The first electrode 155a and second electrode 155b may function as the source electrode and drain electrode of the first transistor structure 210. The active layer 140 may provide a channel region between the source electrode and drain electrode (155a and 155b). A carrier injection layer 153 laterally surrounds each of the source electrode and drain electrode (155a and 155b) and is located between each of the source electrode and drain electrode (155a and 155b) and the active layer 140. The bottom surfaces of the carrier injection layers 153 contact the active layer 140. The bottom surfaces of the carrier injection layers 153 may be recessed relative to the upper surface of the active layer 140 by a recess distance, d, that is at least about 30%, including about 30-70%, of the total thickness, T, of the active layer 140 The carrier injection layers 153 may each include a material having a work function that is between the work function of the source electrode and drain electrode (155a and 155b) and the work function of the active layer 140. In some embodiments, the carrier injection layers 153 may include one or more of zinc oxide (ZnO). gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru).

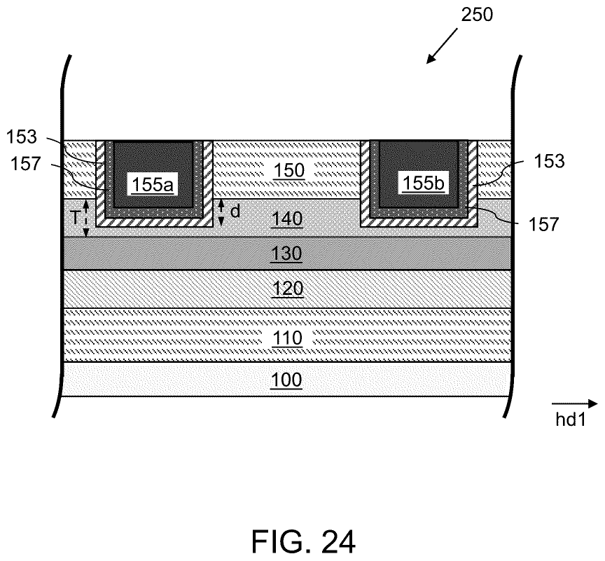

FIG. 24 is a vertical cross-section view of a fifth transistor structure 250 according to an embodiment of the present disclosure. The fifth transistor structure 250 is similar to the fourth transistor structure 240 described above with reference to FIG. 23. The fifth transistor structure 250 differs from the fourth transistor structure 240 in that the carrier injection layers 153 may be first carrier injection layers 153, and the fifth transistor structure 250 may further include second carrier injection layers 157 contacting the first carrier injection layers 153.

The first carrier injection layers 153 and the second carrier injection layers 157 may be equivalent to the first carrier injection layers 153 and the second carrier injection layers 157 described above with reference to FIGS. 13-16. Thus, repeated discussion of the first carrier injection layers 153 and the second carrier injection layers 157 is omitted for brevity. The fifth transistor structure 250 may include a bottom gate electrode layer 120 that is separated from the active layer 140 by a gate insulator layer 130. The first electrode 155a and second electrode 155b may function as the source electrode and drain electrode of the second transistor structure 220. The active layer 140 may provide a channel region between the source electrode and drain electrode (155a and 155b). A first carrier injection layer 153 and a second carrier injection layer 157 laterally surround each of the source electrode and drain electrode (155a and 155b). Each first carrier injection layer 153 contacts side surfaces of the second dielectric material layer 150 and the active layer 140. The bottom surfaces of the first carrier injection layers 153 contact the active layer 140. The bottom surfaces of the first carrier injection layers 153 may be recessed relative to the upper surface of the active layer 140 by a recess distance, d, that is at least about 30%, including about 30-70%, of the total thickness, T, of the active layer 140. Each second carrier injection layer 157 is located between, and contacts, both a first carrier injection layer 153 and either a first electrode 155a or a second electrode 155b. In some embodiments, the first carrier injection layers 153 may have an amorphous structure. In some embodiments, the first carrier injection layers 153 may be composed of a metal oxide material including indium and at least one additional metal (e.g., IZO, IGO, IGZO, IWO, IWZO, IGZTO, etc.). In some embodiments, the first carrier injection layers 153 and the active layer 140 may have an amorphous structure. In some embodiments, both the second carrier injection layers 157 and the first electrode 155a and second electrode 155b may have a crystalline structure. In some embodiments, the work function of the second carrier injection layers 157 may be between the work functions of the active layer 140 and the first electrode 155a and second electrode 155b. In some embodiments, the work functions of both the first carrier injection layers 153 and the second carrier injection layers 157 may be between the work functions of the active layer 140 and the first electrode 155a and second electrode 155b.

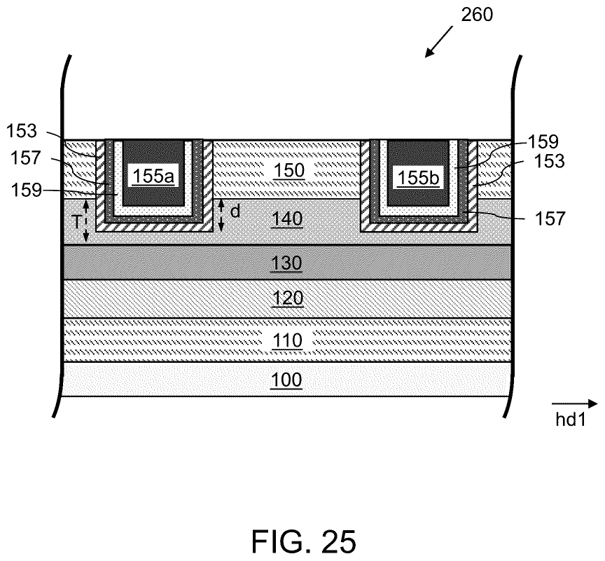

FIG. 25 is a vertical cross-section view of a sixth transistor structure 260 according to an embodiment of the present disclosure. The sixth transistor structure 260 is similar to the fifth transistor structure 250 described above with reference to FIG. 24. The sixth transistor structure 260 further includes a third carrier injection layer 159 as described above with reference to FIGS. 17-20. The sixth transistor structure 260 may include a bottom gate electrode layer 120 that is separated from the active layer 140 by a gate insulator layer 130. The first electrode 155a and second electrode 155b may function as the source electrode and drain electrode of the sixth transistor structure 260. The active layer 140 may provide a channel region between the source electrode and drain electrode (155a and 155b). A first carrier injection layer 153, a second carrier injection layer 157, and a third carrier injection layer 159 laterally surround each of the source electrode and drain electrode (155a and 155b). Each first carrier injection layer 153 contacts side surfaces of the second dielectric material layer 150 and the active layer 140. The bottom surfaces of the first carrier injection layers 153 contact the active layer 140. The bottom surfaces of the first carrier injection layers 153 may be recessed relative to the upper surface of the active layer 140 by a recess distance, d, that is at least about 30%, including about 30-70%, of the total thickness, T, of the active layer 140. Each third carrier injection layer 159 contacts either a first electrode 155a or a second electrode 155b. Each second carrier injection layer 157 is located between a first carrier injection layer 153 and a third carrier injection layer 159. In some embodiments, the first carrier injection layers 153 and the third carrier injection layers 159 may have an amorphous structure. In some embodiments, the first carrier injection layers 153 and the third carrier injection layers 159 may be composed of a metal oxide material including indium and at least one additional metal (e.g., IZO, IGO, IGZO, IWO, IWZO, IGZTO, etc.). In some embodiments, the first carrier injection layers 153, the third carrier injection layers 159 and the active layer 140 may have an amorphous structure. In some embodiments, both the second carrier injection layers 157 and the first and second electrodes 155a and 155b may have a crystalline structure. In some embodiments, the work function of the second carrier injection layers 157 may be between the work functions of the active layer 140 and the first electrode 155a and second electrode 155b. In some embodiments, the work functions of the first carrier injection layers 153, the second carrier injection layers 157, and the third carrier injection layers 159 may be between the work functions of the active layer 140 and the first electrode 155a and second electrode 155b.

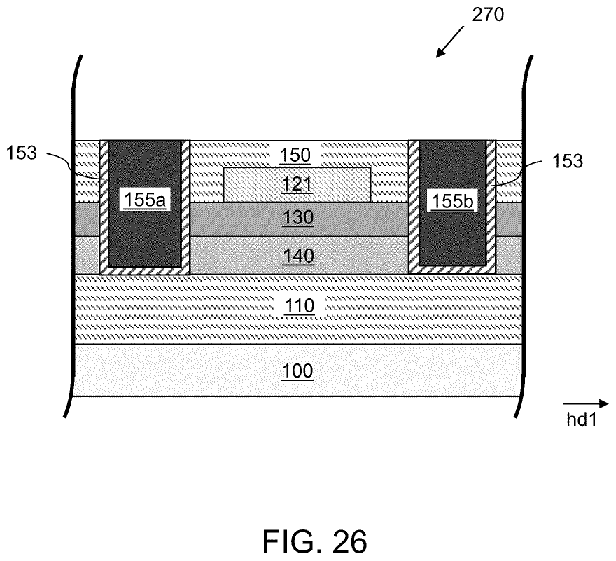

FIG. 26 is a vertical cross-section view of a seventh transistor structure 270 according to an embodiment of the present disclosure. The seventh transistor structure 270 may differ from the first through sixth transistor structures described above in that the seventh transistor structure 270 may have a top gate configuration. That is, the above-described bottom gate electrode layer 120 may be omitted, and an active layer 140 as described above may be formed over the first dielectric material layer 110. An above-described gate insulator layer 130 may then be formed over the active layer 140. A top gate electrode 121 may then be formed over the gate insulator layer 130.

The top gate electrode 121 may be formed by depositing a suitable electrically conductive material using a suitable deposition process and patterning the electrically conductive material using a suitable patterning technique as described above to provide a discrete top gate electrode 121 over the gate insulator layer 130. The top gate electrode 121 may be surrounded on its top and side surfaces by the second dielectric material layer 150. Then, the process steps described above with reference to FIGS. 7-12 may be performed to form openings through the second dielectric material layer 150, the gate insulator layer 130 and the active layer 140, form carrier injection layers 153 over the sidewalls and bottom surfaces of the openings, and form first electrode 155a and second electrode 155b over the carrier injection layers 153 within each of the openings.

The seventh transistor structure 270 may include a first dielectric material layer 110, an active layer 140 over the first dielectric material layer 110, a gate insulator layer 130 over the active layer 140, and a top gate electrode 121 over the gate insulator layer 130. A second dielectric material layer 150 may laterally surround the top gate electrode 121. First electrode 155a and second electrode 155b (i.e., source and drain electrodes) may extend through the second dielectric material layer 150, the gate insulator layer 130 and the active layer 140. The top gate electrode 121 may be located between the source electrode and drain electrode (155a and 155b). A carrier injection layer 153 laterally surrounds each of the source and drain electrodes 155a and 155b and is located between each of the source electrode and drain electrode (155a and 155b) and the active layer 140. Bottom surfaces of the carrier injection layers 153 contact first dielectric material layer 110. The carrier injection layers 153 each include a material having a work function that is between the work function of the source electrode and drain electrode (155a and 155b) and the work function of the active layer 140. In some embodiments, the carrier injection layers 153 may include one or more of zinc oxide (ZnO). gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru).

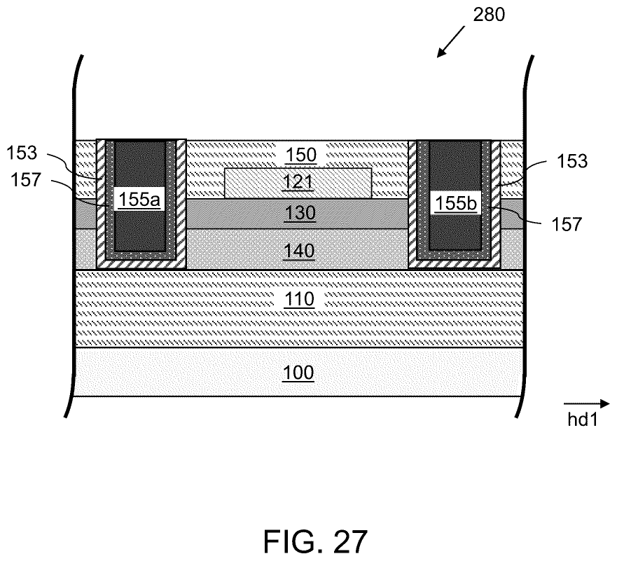

FIG. 27 is a vertical cross-section view of an eighth transistor structure 280 according to an embodiment of the present disclosure. The eighth transistor structure 280 is similar to the top-gate seventh transistor structure 270 of FIG. 26. Thus, repeated discussion of like elements is omitted for brevity. The eighth transistor structure 280 differs from the seventh transistor structure 270 by including both first carrier injection layers 153 and second carrier injection layers 157 as described above.

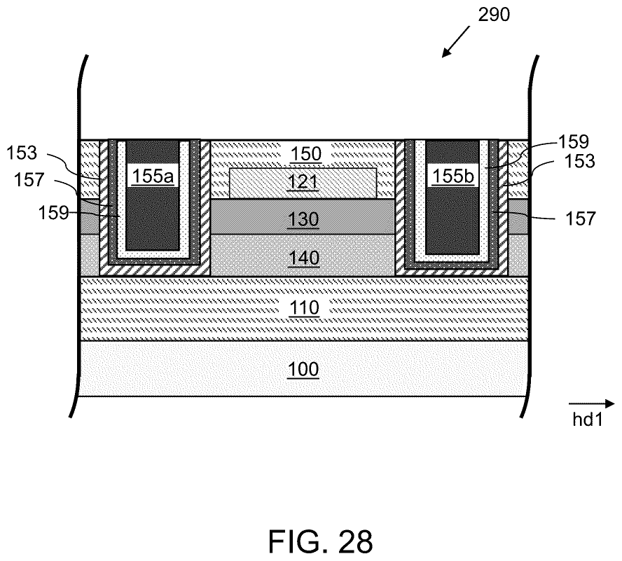

FIG. 28 is a vertical cross-section view of an ninth transistor structure 290 according to an embodiment of the present disclosure. The ninth transistor structure 290 is similar to the top-gate seventh transistor structure 270 of FIG. 26. Thus, repeated discussion of like elements is omitted for brevity. The ninth transistor structure 290 differs from the seventh transistor structure 270 by including first carrier injection layers 153, second carrier injection layers 157, and third carrier injection layers 159 as described above.

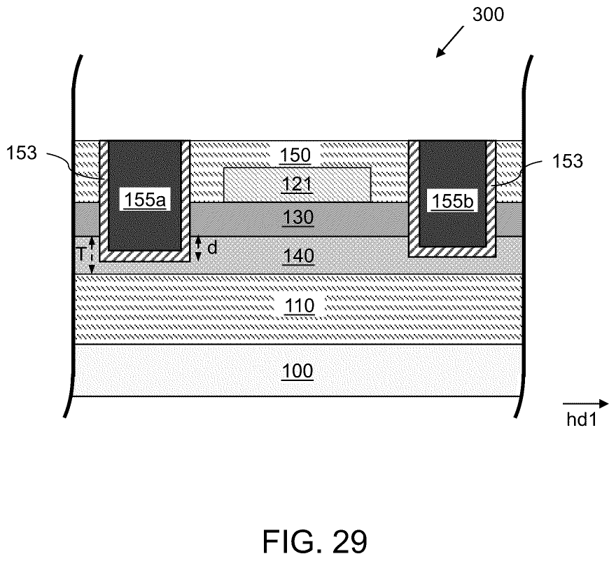

FIG. 29 is a vertical cross-section view of a tenth transistor structure 300 according to an embodiment of the present disclosure. The tenth transistor structure 300 may have a top gate configuration as described above with reference to FIGS. 26-28. The tenth transistor structure 300 may differ from the structures of FIGS. 26-28 in that the openings formed through the second dielectric material layer 150, the gate insulator layer 130 and the active layer 140 may not extend through the entire thickness of the active layer 140 to the first dielectric material layer 110. Thus, in the tenth transistor structure 300 of FIG. 29, the bottom surfaces of the carrier injection layers 153 may contact the active layer 140 rather than the first dielectric material layer 110. In some embodiments, the bottom surfaces of the carrier injection layers 153 may be recessed relative to the upper surface of the active layer 140 by a recess distance, d, that is at least about 30%, including about 30-70%, of the total thickness, T, of the active layer 140.

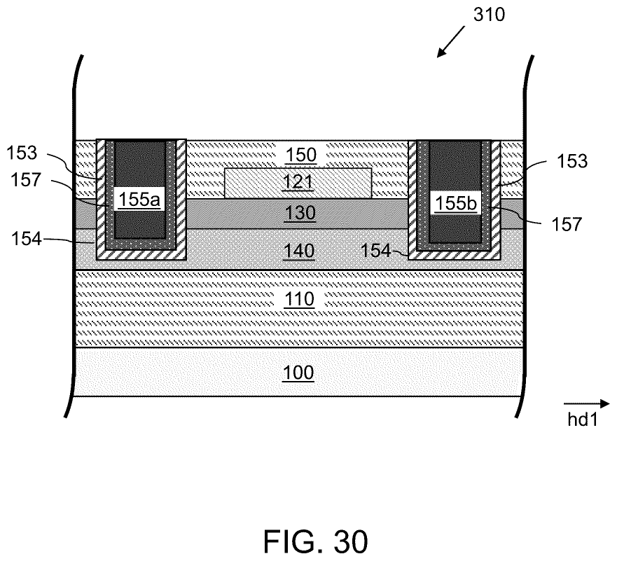

FIG. 30 is a vertical cross-section view of an eleventh transistor structure 310 according to an embodiment of the present disclosure. The eleventh transistor structure 310 is similar to the tenth transistor structure 300 of FIG. 29. Thus, repeated discussion of like elements is omitted for brevity. The eleventh transistor structure 310 differs from the tenth transistor structure 300 by including both first carrier injection layers 153 and second carrier injection layers 157 as described above.

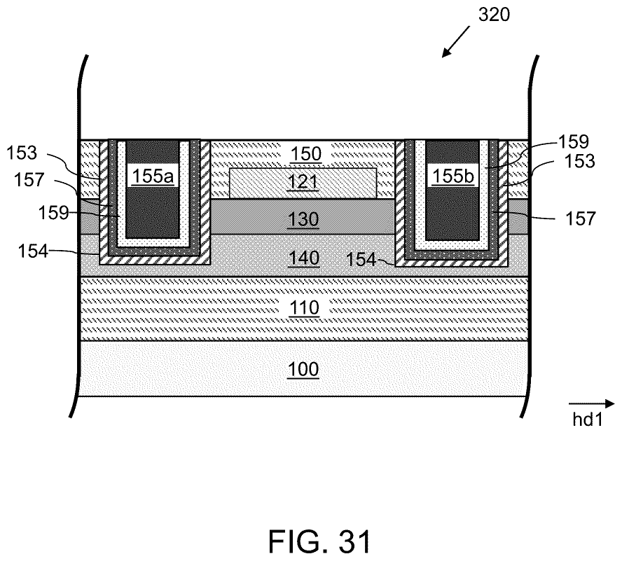

FIG. 31 is a vertical cross-section view of a twelfth transistor structure 320 according to an embodiment of the present disclosure. The twelfth transistor structure 320 is similar to the tenth transistor structure 300 of FIG. 29. Thus, repeated discussion of like elements is omitted for brevity. The twelfth transistor structure 320 differs from the tenth transistor structure 300 by including first carrier injection layers 153, second carrier injection layers 157, and third carrier injection layers as described above.

Although various embodiments described and illustrated herein have included transistor structures 210, 220, 230, 240, 250, 260, 270, 280, 290, 300, 310, and 320 that have been fabricated using a BEOL process, it will be understood that transistor structures including one or more carrier injection layers as described herein may also be formed using front-end-of-line (FEOL) process. In such embodiments, the above-described active layer 140 may include a semiconductor material layer 9 shown in FIG. 1.

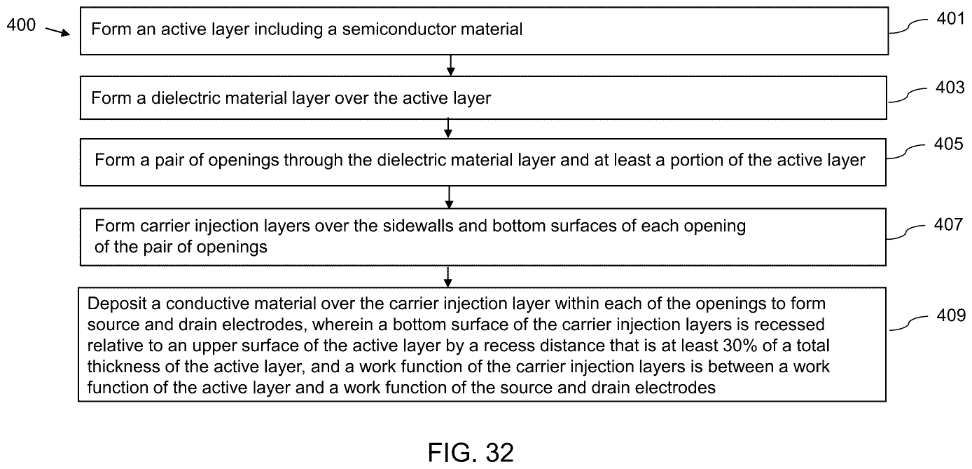

FIG. 32 is a flow diagram illustrating a method 400 for fabricating a transistor structure 210, 220, 230, 240, 250, 260, 270, 280, 290, 300, 310, and 320 according to various embodiments of the present disclosure. Referring to FIGS. 5 and 32, in step 401 of embodiment method 400 an active layer 140 including a semiconductor material may be formed. Referring to FIGS. 6 and 32, in step 403 of embodiment method 400, a dielectric material layer 150 may be formed over the active layer 140. Referring to FIGS. 7, 8, 21 and 32, in step 405 of embodiment method 400, a pair of openings 152 may be formed through the dielectric material layer 150 and at least a portion of the active layer 140. Referring to FIGS. 9, 10, 13, 14, 17, 18, 22 and 32, in step 407 of embodiment method 400, carrier injection layers 153, 157, 159 may be formed over the sidewalls and bottom surfaces of each opening 152 of the pair of openings 152. Referring to FIGS. 11, 12, 15, 16, 19, 20, 23 and 32, in step 409 of embodiment method 400, a conductive material 155 may be deposited over the carrier injection layer 153, 157, 159 within each of the openings 152 to form source electrode and drain electrode (155a and 155b), where a bottom surface of the carrier injection layers 153 is recessed relative to the upper surface of the active layer 140 by a recess distance, d, that is at least 30% of a total thickness, T, of the active layer 140, and a work function of the carrier injection layers 153, 157 and 159 is between a work function of the active layer 140 and a work function of the source and drain electrodes 155a and 155b.

Referring to all drawings and according to various embodiments of the present disclosure, a transistor structure (210, 220, 230, 240, 250, 260, 270, 280, 290, 300, 310, 320) includes a gate electrode layer (120, 121), an active layer 140 including a semiconductor material, a gate insulator layer 130 between the gate electrode layer (120, 121) and the active layer 140, a dielectric material layer 150 over the active layer 140, source electrode and drain electrode (155a and 155b) extending through the dielectric material layer 150 and at least partially into the active layer 140, and at least one carrier injection layer (153, 157, 159) laterally surrounding each of the source electrode and drain electrode (155a and 155b), where a bottom surface of the at least one carrier injection layer (153, 157, 159) is recessed relative to an upper surface of the active layer 140 by a recess distance d that is at least 30% of a total thickness T of the active layer 140, and a work function of the at least one carrier injection layer (153, 157, 159) is between a work function of the active layer 140 and a work function of the source electrode and drain electrode (155a and 155b).

In an embodiment, the gate insulator layer 130 and the gate electrode layer 120 are located below the active layer 140 and the at least one carrier injection layer 153 contacts side surfaces of the dielectric material layer 150 and the active layer 140.

In another embodiment, the bottom surface of the at least one carrier injection layer 153 contacts an upper surface of the gate insulator layer 130.

In another embodiment, the bottom surface of the at least one carrier injection layer 153 contacts the active layer 140, and the bottom surface of the at least one carrier injection layer 153 is recessed relative to an upper surface of the active layer 140 by a recess distance d that is between 30% and 70% of the total thickness T of the active layer 140.

In another embodiment, the at least one carrier injection layer 153 contacts either a source electrode 155a or a drain electrode 155b, and the at least one carrier injection layer 153 includes at least one of zinc oxide (ZnO). gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru).

In another embodiment, the at least one carrier injection layer includes a first carrier injection layer 153 and a second carrier injection layer 157 surrounding each of the source electrode and drain electrode (155a and 155b), where the first carrier injection layer 153 contacts the active layer 140 and the second carrier injection layer 157 is located between the first carrier injection layer 153 and the source or drain electrode (155a, 155b), and the first carrier injection layer 153 and the second carrier injection layer 157 are composed of different materials.

In another embodiment, the first carrier injection layer 153 and the active layer 140 have an amorphous structure, the second carrier injection layer 157 and the source electrode and drain electrode (155a and 155b) have a crystalline structure, and the work function of the second carrier injection layer 157 is between the work function of the active layer 140 and the work function of the source electrode and drain electrode (155a and 155b).

In another embodiment, the first carrier injection layer 153 includes a metal oxide material comprising indium and at least one additional metal, and the first carrier injection layer 153 has an amorphous structure.

In another embodiment, the first carrier injection layer 153 includes one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO), and the second carrier injection layer 157 includes one or more of zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti).

In another embodiment, the at least one carrier injection layer further includes a third carrier injection layer 159, the second carrier injection layer 157 is located between the first carrier injection layer 153 and the third carrier injection layer 159, and the third carrier injection layer 159 includes one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO).

In another embodiment, a total thickness of the first carrier injection layer 153, the second carrier injection layer 157 and the third carrier injection layer 159 is 5 nm or less.

In another embodiment, the dielectric material layer over the active layer 140 includes a second dielectric material layer 150, the transistor structure further including a first dielectric material layer 110, where the active layer 140 is located over the first dielectric material layer 110, the gate insulator layer 130 is located over the active layer 140, the gate electrode layer 121 is located over the gate insulator layer 130, and the gate electrode layer 121 is located between the source electrode and drain electrode (155a and 155b) and is laterally surrounded by the second dielectric material layer 150, and where the at least one carrier injection layer 153 contacts side surfaces of the second dielectric material layer 150, the gate insulator layer 130 and the active layer 140.

In another embodiment, the bottom surface of the at least one carrier injection layer 153 contacts an upper surface of the first dielectric material layer 110.

Another embodiment is drawn to a transistor structure (220, 230, 250, 260, 280, 290, 310, 320) including a gate electrode layer (120, 121), an active layer 140 including a semiconductor material, a gate insulator layer 130 between the gate electrode layer (120, 121) and the active layer 140, a dielectric material layer 150 over the active layer 140, a first electrode (155a, 155b) extending through the dielectric material layer 150 and at least partially into the active layer 140, a first carrier injection layer 153 laterally surrounding the first electrode (155a, 155b) and contacting side surfaces of the dielectric material layer 150 and the active layer 140, and a second carrier injection layer 157 laterally surrounding the first electrode (155a, 155b), where the second carrier injection layer 157 is located between the first carrier injection layer 153 and the first electrode (155a, 155b), the first carrier injection layer 153 includes a metal oxide material comprising indium and at least one additional metal, and the first carrier injection layer 153 has an amorphous structure, and the second carrier injection layer 157 has a composition that is different than the first carrier injection layer 153.

In an embodiment, the active layer 140 includes an amorphous structure, and the first electrode (155a, 155b) and the second carrier injection layer 157 include a crystalline structure.

In another embodiment, the first carrier injection layer 153 includes one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO), and the second carrier injection layer 157 includes one or more of zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti).

In another embodiment, the transistor structure further includes a third carrier injection layer 159 laterally surrounding the first electrode (155a, 155b), where the second carrier injection layer 157 is located between the first carrier injection layer 153 and the third carrier injection layer 159, where the third carrier injection layer 159 has a composition that is different than the second carrier injection layer 157, and both the first carrier injection layer 153 and the third carrier injection layer 159 include metal oxide materials including indium and at least one additional metal.

Another embodiment is drawn to a method of fabricating a transistor structure that includes forming an active layer 140 including a semiconductor material, forming a dielectric material layer 150 over the active layer 140, forming a pair of openings 152 through the dielectric material layer 150 and at least a portion of the active layer 140, forming a carrier injection layer 159 over sidewalls and a bottom surface of each opening 152 of the pair of openings 152, depositing a conductive material 155 over the carrier injection layer 159 within each of the openings 152 to form the source electrode and drain electrode (155a and 155b), where a bottom surface of each of the carrier injection layers 153 is recessed relative to an upper surface of the active layer 140 by a recess distance d that is at least 30% of a total thickness T of the active layer 140, and a work function of the carrier injection layers 153 is between a work function of the active layer 140 and a work function of the source electrode and the drain electrode (155a, 155b).

In an embodiment, the method further includes forming a gate electrode layer 120, and forming a gate insulator layer 130 over the gate electrode layer 120, where the active layer 140 is formed over the gate insulator layer 130.

In another embodiment, the method further includes forming a gate insulator layer 130 over the active layer 140, and forming a gate electrode layer 121 over the gate insulator layer 130, where the dielectric material layer 150 laterally surrounds the gate electrode layer 121, and the pair of openings 152 are formed through the dielectric material layer 150, the gate insulator layer 130, and at least a portion of the active layer 140 on opposite sides of the gate electrode layer 121.

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A transistor structure, comprising:
a gate electrode layer;
an active layer comprising a semiconductor material;
a gate insulator layer between the gate electrode layer and the active layer;
a dielectric material layer over the active layer;
a source electrode and a drain electrode extending through the dielectric material layer and at least partially into the active layer; and
at least one carrier injection layer laterally surrounding each of the source electrode and the drain electrode, wherein a bottom surface of the at least one carrier injection layer is recessed relative to an upper surface of the active layer by a recess distance that is at least 30% of a total thickness of the active layer, and a work function of the at least one carrier injection layer is between a work function of the active layer and a work function of the source electrode and the drain electrode.

2. The transistor structure of claim 1, wherein the gate insulator layer and the gate electrode layer are located below the active layer and the at least one carrier injection layer contacts side surfaces of the dielectric material layer and the active layer.

3. The transistor structure of claim 2, wherein the bottom surface of the at least one carrier injection layer contacts an upper surface of the gate insulator layer.

4. The transistor structure of claim 2, wherein the bottom surface of the at least one carrier injection layer contacts the active layer, and the bottom surface of the at least one carrier injection layer is recessed relative to an upper surface of the active layer by a recess distance that is between 30% and 70% of the total thickness of the active layer.

5. The transistor structure of claim 1, wherein the at least one carrier injection layer contacts either the source electrode or the drain electrode and the at least one carrier injection layer comprises at least one of zinc oxide (ZnO), gallium oxide (GaO), indium oxide (InO), nickel oxide (NiO), titanium oxide (TiO), cobalt (Co), nickel (Ni), titanium nitride (TiN), tantalum nitride (TaN), titanium (Ti), and ruthenium (Ru).

6. The transistor structure of claim 1, wherein the at least one carrier injection layer comprises a first carrier injection layer and a second carrier injection layer surrounding each of the source electrode and drain electrode, wherein the first carrier injection layer contacts the active layer and the second carrier injection layer is located between the first carrier injection layer and the source electrode or the drain electrode, and the first carrier injection layer and the second carrier injection layer are composed of different materials.

7. The transistor structure of claim 6, wherein the first carrier injection layer and the active layer have an amorphous structure, the second carrier injection layer and the source electrode and the drain electrode have a crystalline structure, and the work function of the second carrier injection layer is between the work function of the active layer and the work function of the source electrode and the drain electrode.

8. The transistor structure of claim 6, wherein the first carrier injection layer comprises a metal oxide material comprising indium and at least one additional metal, and the first carrier injection layer has an amorphous structure.

9. The transistor structure of claim 8, wherein the first carrier injection layer comprises one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO), and the second carrier injection layer comprises one or more of zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti).

10. The transistor structure of claim 6, wherein the at least one carrier injection layer further comprises a third carrier injection layer, the second carrier injection layer is located between the first carrier injection layer and the third carrier injection layer, and the third carrier injection layer comprises one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO).

11. The transistor structure of claim 10, wherein total thickness of the first carrier injection layer, the second carrier injection layer and the third carrier injection layer is 5 nm or less.

12. The transistor structure of claim 1, wherein the dielectric material layer over the active layer comprises a second dielectric material layer, the transistor structure further comprising:
a first dielectric material layer, wherein the active layer is located over the first dielectric material layer, the gate insulator layer is located over the active layer, the gate electrode layer is located over the gate insulator layer, and the gate electrode layer is located between the source electrode and the drain electrode and is laterally surrounded by the second dielectric material layer, and wherein the at least one carrier injection layer contacts side surfaces of the second dielectric material layer, the gate insulator layer and the active layer.

13. The transistor structure of claim 12, wherein the bottom surface of the at least one carrier injection layer contacts an upper surface of the first dielectric material layer.

14. A transistor structure, comprising:
a gate electrode layer;
an active layer comprising a semiconductor material;
a gate insulator layer between the gate electrode layer and the active layer;
a dielectric material layer over the active layer;
a first electrode extending through the dielectric material layer and at least partially into the active layer;
a first carrier injection layer laterally surrounding the first electrode and contacting side surfaces of the dielectric material layer and the active layer; and
a second carrier injection layer laterally surrounding the first electrode, wherein the second carrier injection layer is located between the first carrier injection layer and the first electrode, the first carrier injection layer comprises a metal oxide material comprising indium and at least one additional metal, and the first carrier injection layer has an amorphous structure, and the second carrier injection layer has a composition that is different than the first carrier injection layer.

15. The transistor structure of claim 14, wherein the active layer comprises an amorphous structure, and the first electrode and the second carrier injection layer comprise a crystalline structure.

16. The transistor structure of claim 14, wherein the first carrier injection layer comprises one or more of indium zinc oxide (IZO), indium gallium oxide (IGO), indium gallium zinc oxide (IGZO), indium tungsten oxide (IWO), indium tungsten zinc oxide (IWZO), and indium gallium zinc tin oxide (IGZTO), and the second carrier injection layer comprises one or more of zinc oxide (ZnO), gallium oxide (GaO), indium oxide (InO), nickel oxide (NiO), titanium oxide (TiO)), cobalt, nickel (Ni), titanium nitride (TiN), tantalum nitride (TaN), and titanium (Ti).

17. The transistor structure of claim 16, further comprising:
a third carrier injection layer laterally surrounding the first electrode, wherein the second carrier injection layer is located between the first carrier injection layer and the third carrier injection layer, wherein the third carrier injection layer has a composition that is different than the second carrier injection layer, and both the first carrier injection layer and the third carrier injection layer comprise metal oxide materials comprising indium and at least one additional metal.

18. A method of fabricating a transistor structure, comprising:
forming an active layer comprising a semiconductor material;
forming a dielectric material layer over the active layer;
forming a pair of openings through the dielectric material layer and at least a portion of the active layer;
forming a carrier injection layer over sidewalls and a bottom surface of each opening of the pair of openings; and
depositing a conductive material over the carrier injection layer within each of the openings to form a source electrode and a drain electrodes, wherein a bottom surface of the carrier injection layer within each of the openings is recessed relative to an upper surface of the active layer by a recess distance that is at least 30% of a total thickness of the active layer, and a work function of the carrier injection layer is between a work function of the active layer and a work function of the source electrode and drain electrode.

19. The method of claim 18, further comprising:
forming a gate electrode layer; and
forming a gate insulator layer over the gate electrode layer, wherein the active layer is formed over the gate insulator layer.

20. The method of claim 18, further comprising:
forming a gate insulator layer over the active layer; and
forming a gate electrode layer over the gate insulator layer, wherein the dielectric material layer laterally surrounds the gate electrode layer, and the pair of openings are formed through the dielectric material layer, the gate insulator layer, and at least a portion of the active layer on opposite sides of the gate electrode layer.
